(19) United States
(12) Patent Application Publication
(10) Pub. No.: US 2014/0379333 A1
(43) Pub. Date: Dec. 25, 2014

(54) WAVEFORM RESYNTHESIS

(71) Applicant: Lloyd Trammell, Thousand Oaks, CA (US)

(72) Inventor: Lloyd Trammell, Thousand Oaks, CA (US)

(73) Assignee: Max Sound Corporation, La Jolla, CA (US)

(21) Appl. No.: 14/184,625

(22) Filed: Feb. 19, 2014

Related U.S. Application Data
(60) Provisional application No. 61/766,657, filed on Feb. 19, 2013.

(51) Int. Cl. G10L 19/26; H03K 5/00

(52) U.S. Cl. CPC G10L 19/26; H03K 5/00006
USPC 704/220; 327/105

(57) ABSTRACT

A wave resynthesis method and system comprises receiving input wave form, processing received data to create an enhanced wave form, identifying the enhanced wave form, transmitting the identified wave form to a receiving unit, identifying the received wave form, resynthesizing the received wave form and outputting the resynthesized wave form. Identifying the enhanced wave form includes sampling the waveform and measuring the angle of the samples at two or more points in the waveform. The enhancing of voice audio input includes the parallel processing the input audio by a module that is a low pass filter with dynamic offset, an envelope controlled band-pass filter, a high pass filter and adding an amount of dynamic synthesized sub bass to the audio. The four processed audio signals are combined in a summing mixer with the original audio. The receiving unit has a complete set of encrypted tables for accurate resynthesizing/reproduction.

### CROSS-REFERENCE TO RELATED PATENT APPLICATIONS

Embodiments of the present invention relate to U.S. Provisional Application Ser. No. 61/766,657, filed Feb. 19, 2013, entitled “METHOD FOR RESYNTHESIZING WAVE”, the contents of which are incorporated by reference herein and which is a basis for a claim of priority

### BACKGROUND OF THE INVENTION

Data transmission in the real world takes time and the fastest it can go is the speed of light. For example, one of the rovers on Mars is given a command and the person controlling the rover has to wait until the rover receives the command before it can process that command. That takes approximately 4.3 to 21 minutes, depending on the position of Mars to the Earth. Many events could occur during this travel time, leaving the controller with possibly catastrophic results for the rover.

In many cases the medium in which the wave is being propagated does not permit a direct visual image of the form. In these cases, the term ‘waveform’ refers to the shape of a graph of the varying quantity against time or distance. An instrument called an oscilloscope can be used to pictorially represent a wave as a repeating image on a screen. By extension, the term ‘waveform’ also describes the shape of the graph of any varying quantity against time.

Common periodic waveforms include (t is time):
Sine wave: sin (2πt). The amplitude of the waveform follows a trigonometric sine function with respect to time.
Square wave: saw(t)−saw (t−duty). This waveform is commonly used to represent digital information. A square wave of constant period contains odd harmonics that fall off at −6 dB/octave.
Triangle wave: (t−2 floor ((t+1)/2)) (−1)floor ((t+1)/2). It contains odd harmonics that fall off at −12 dB/octave.
Sawtooth wave: 2 (t−floor(t))−1. This looks like the teeth of a saw. Found often in time bases for display scanning. It is used as the starting point for subtractive synthesis, as a sawtooth wave of constant period contains odd and even harmonics that fall off at −6 dB/octave.

Other waveforms are often called composite waveforms and can often be described as a combination of a number of sinusoidal waves or other basis functions added together.

In mathematics, a periodic function is a function that repeats its values in regular intervals or periods. The most important examples are the trigonometric functions, which repeat over intervals of 2π radians. Periodic functions are used throughout science to describe oscillations, waves, and other phenomena that exhibit periodicity.

### SUMMARY OF THE INVENTION

A wave resynthesis method and system according to the present invention comprises receiving input wave form, processing received data to create an enhanced wave form, identifying the enhanced wave form, transmitting the identified wave form to a receiving unit, identifying the received wave form, resynthesizing the received wave form and outputting the resynthesized wave form.

Identifying the enhanced wave form includes sSampling the waveform and measuring the angle of the samples at two or more points in the waveform. The enhancing of voice audio input includes the parallel processing the input audio by a module that is a low pass filter with dynamic offset, an envelope controlled band-pass filter, a high pass filter and adding an amount of dynamic synthesized sub bass to the audio. The four processed audio signals are combined in a summing mixer with the original audio. The receiving unit has a complete set of encrypted tables for accurate resynthesizing/reproduction.

### BRIEF DESCRIPTION OF THE DRAWINGS

FIG. 1 is a block diagram of an exemplary embodiment of the Waveform Resynthesis process s of the present invention.

FIG. 2 shows several examples of a sine waveform.

FIG. 3 is shows the Max Sound Process, according to an exemplary embodiment of the present invention.

### DETAILED DESCRIPTION OF THE INVENTION

Against this background of what a waveform is and what a single waveform contains, the inventive LTWR process extracts information from these waveforms rapidly and can begin to identify or recreate said waveforms in real-time. This process is a DSP process with either an analog or digital input source intended to be used as the input. The process can run as stand alone or embedded part of a system package.

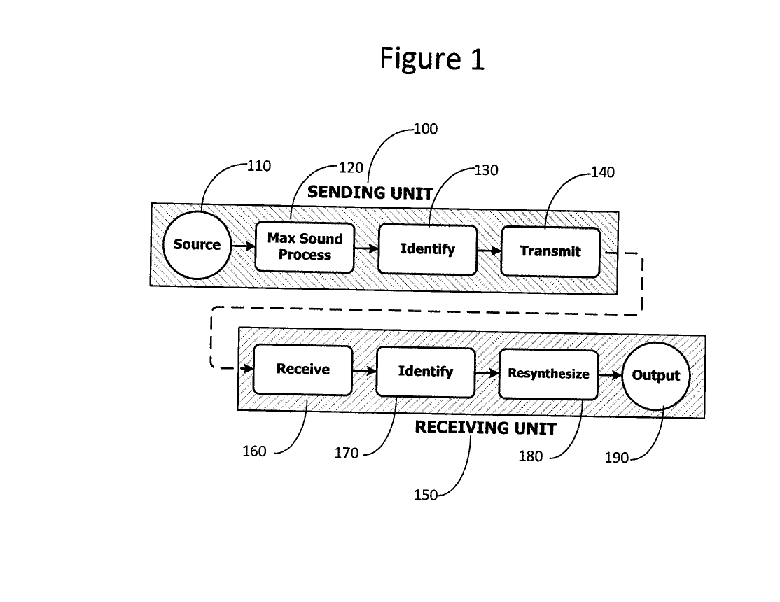

The method and system of the inventive LTWR will now be discussed with reference to the drawings. Referring to FIG. 1, Source Waveform 110 is provided. Source 100 can be analog or digital. After entering Sending Unit 100 source audio 110 is sent to the Max Sound Process module 120 for processing. The Identify 130 block identifies the waveforms (the LTWR waveform identification process described later in this document) and is subsequently sent out by Transmit 140 out of the Sending Unit 100. This output signal can be digital or analog and can be sent to the Receiving Unit in a number of ways, such as radio, hardwire, or any method used for communication.

Output signal sent by Transmit 140 is received by the Receiving Unit 150 which then identifies the signal and immediately starts resynthesizing (recreating) the signal as a complete, whole waveform as the original source was. These two separate units (100, 150) make a complete “system” that is not only extremely fast, but also very secure. Unless both units are in communication, the output from the sending unit is unusable in the common realm of communications and control.

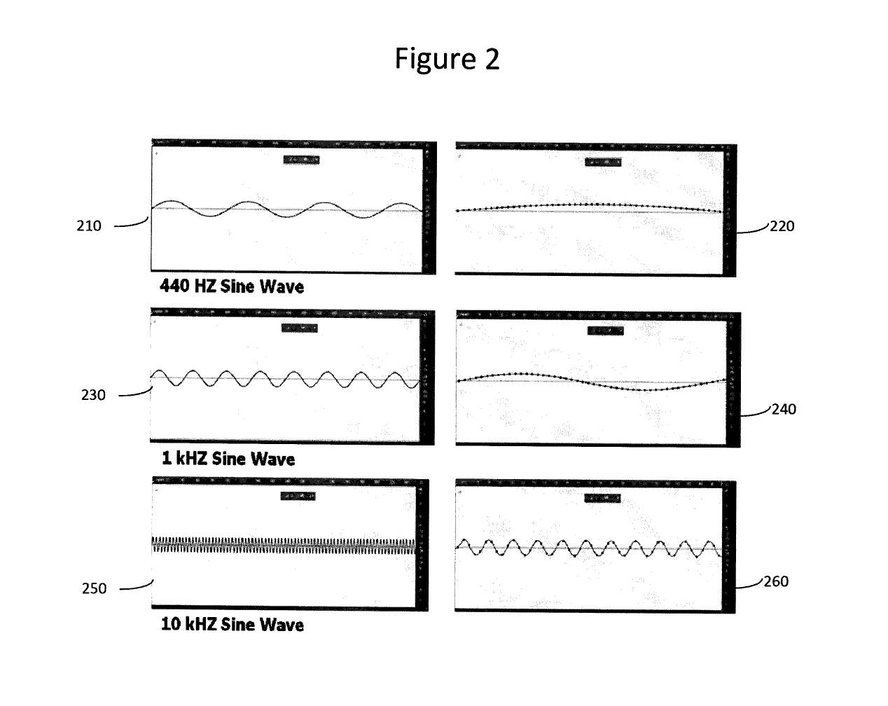

FIG. 2 shows some examples of sine waves of specific frequencies according to an embodiment of the present invention.

1. 440 Hz−left=@350 samples right=@48 samples

2. 1 kHz−left=@350 samples right=@48 samples

3. 10 kHz−left=@350 samples right=@48 samples

The sample rate is 44.1 kHz for all of the examples. The amplitude is +/−16 dB on the scale. Examples on the left, identified by reference numerals 210, 230 and 250, show multiple cycles of the waves sampled at CD quality 44.1 kHz. The examples on the right, identified by reference numerals 220, 240 and 260, are zoomed in so that the divisions of the wave by 44,100 slices per second can be seen. Each dot represents a single division of the entire wave and has an angle, specific to that wave frequency, between the dots.

In both instances, the vertical is amplitude while the horizontal is time. The line in the center is the “zero crossing” point of the wave.

In one embodiment, the inventive LTWR is carried out in real-time and any change generates a corresponding response that is sent to the Receiving Unit 150, also in real time. If a set of waveforms that are about 10 seconds long are sent at one time, the entire set is still 10 seconds using conventional methods. By using the LTWR that entire set can be shortened to as little as 1/1000th of that, and perhaps even more.

In one embodiment, the inventive LTWR will receive and identify a waveform in as little as three samples and send that information through the system as a very small piece of data. As soon as the data is received on the other end, a complete waveform will be generated (these are turned into an encrypted table) and output to wherever its destination. According to a preferred embodiment the LTWR identifies a waveform is by measuring the angle of the samples as the pass through the LTWR process. Every frequency corresponds to a specific angle that is constant. As stated above, if the sample rate is 44.1 kHz (CD quality) then the there is 44,100 divisions (samples) per second of the audio. Each of these is a separate point in that audio. If the angle is measured at two or more points in the wave it provides a very accurate representation of the wave without seeing or hearing the entire note.

If a waveform changes, then it is analyzed the same way and a corresponding table is sent to the Receiving Unit for resynthesizing. The Receiving Unit has a complete set of encrypted tables for accurate resynthesizing/reproduction. The inventive LTWR process is based on the principle that sending smaller chunks of data results in the signals being received in less total time than the corresponding time for long original data, thus saving time especially over long distances or anytime an extremely fast response is required. This has applications for communications of both civilian and military uses, both auditory and control uses.

The inventive method can be used as either monophonic (single note) or polyphonic (multiple notes) in order to identify notes or chords in music. The applications for this are practically limitless, including music, machine command that are sent to a device that is miles away in an extremely short burst, such as milliseconds instead of several seconds, etc. All that need be sent are a few sample information for the receiver to identify the complete waveform in a much shorter than the time required to send the entire wave and have it identified.

The inventive LTWR can be utilized in satellite communications, control communications, basically any type of communication that is needed to transmit. In music specifically, the LTWR process can resynthesis partial or mostly missing data in real time for greatly enhanced audio content. Compressed audio can be restored to full harmonic, dynamic, and phase coherent as it started.

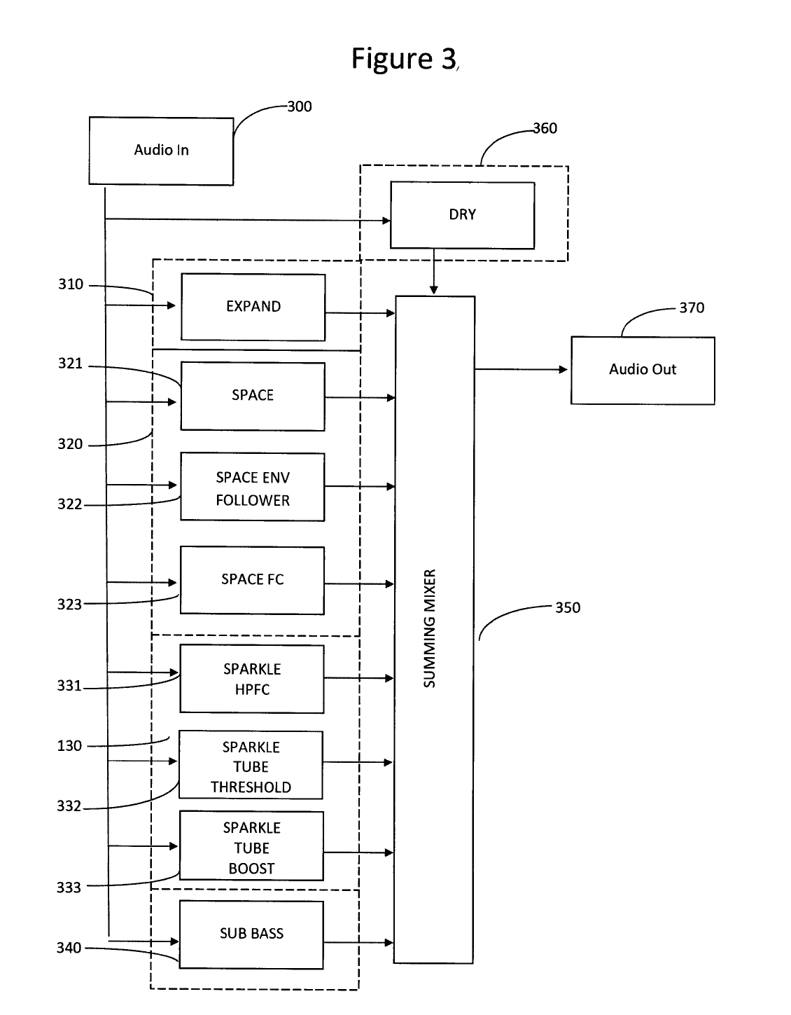

The details of the present invention will now be further described with reference to the drawings in FIG. 3. Waveform input 100 is provided.

EXPAND 310 is preferably a 4 pole digital low pass filter with an envelope follower for dynamic offset (fixed envelope follower). This allows the output of the filter to be dynamically controlled so that the output level is equal to whatever the input is to this filter section. For e.g., if the level at the input is −6 dB, then the output will match that. Moreover, whenever there is a change at the input, the same change will occur at the output regardless of either positive or negative amounts. The frequency for this filter is, e.g., 20 to 20 k hertz, which corresponds to a full range. The purpose of EXPAND 310 is to “warm up” or provide a fuller sound as waveform 100 passes through it. The original audio 300 passes through, and is added to the effected sound for its output. As the input amount varies, so does the phase of this section. This applies to all filters used in this software application. Preferably all filters are of the Butterworth type.

Next, we discuss SPACE 320. In FIG. 3, SPACE 120 refers to the block of three modules identified by reference numerals 321, 322 and 323. The first module SPACE 321—which follows EXPAND 310 envelope follower, sets the final level of this module. This is the effected signal only, without the original. SPACE ENV FOLLOWER 322 tracks the input amount and forces the output level of this section to match. SPACE FC 323 sets the center frequency of the 4 pole digital high pass filter used in this section. This filter also changes phase as does EXPAND 310.

SPACE blocks 320 are followed by the SPARKLE 330 blocks. Like SPACE 320, there are several components to SPARKLE. SPARKLE HPFC 331 is a 2 pole high pass filter with a preboost which sets the lower frequency limit of this filter. Anything above this setting passes through the filter while anything below is discarded or stopped from passing. SPARKLE TUBE THRESH 332 sets the lower level at which the tube simulator begins working. As the input increases, so does the amount of the tube sound. The tube sound adds harmonics, compression and a slight bit of distortion to the input audio 300. This amount increases slightly as the input level increases. SPARKLE TUBE BOOST 333 sets the final level of the output of this module. This is the effected signal only, without the original.

Next, the SUB BASS 340 module is discussed. This module takes the input signal and uses a low pass filter to set the upper frequency limit to about 100 Hz. An octave divider occurs in the software that changes the input signal to lower by an octave (12 semi tones) and output to the only control in the interface, which is the level or the final amount. This is the effected signal only, without the original.

Outputs from all of the above modules 310 to 340 are directed into SUMMING MIXER 350 which combines the audio. The levels going into the summing mixer 350 are controlled by the various outputs of the modules listed above. As they all combine with the original signal 300 fed through the DRY 360 module there is interaction in phase, time and frequencies that occur dynamically. These changes all combine to create a very pleasing audio experience for the listener in the form of “enhanced” audio content. For example, a change in a single module can have a great affect on what happens in relation to the other modules final sound or the final harmonic output of the entire software application.

What is claimed is:

1. A wave resynthesis method and system comprising:
Receiving input wave form;
Processing received data to create an enhanced wave form;
Identifying the enhanced wave form;
Transmitting the identified wave form to a receiving unit;
Identifying the received wave form;
Resynthesizing the received wave form;
Outputting the resynthesized wave form.

2. The method of claim 1, wherein the identifying the enhanced wave form comprises:
Sampling the waveform
Measuring the angle of the samples at two or more points in the waveform.

3. The system of claim 1 wherein the enhancing of voice audio input includes the parallel processing the input audio as follows:
A module that is a low pass filter with dynamic offset;
An envelope controlled band-pass filter;
A high pass filter;
Adding an amount of dynamic synthesized sub bass to the audio; and
Combining the four treated audio signals in a summing mixer with the original audio

4. The method of claim 1 wherein the receiving unit has a complete set of encrypted tables for accurate resynthesizing/reproduction.
